(19) United States
(12) Patent Application Publication
(10) Pub. No.: US 2025/0266832 A1
(43) Pub. Date: Aug. 21, 2025

(54) DIFFERENTIAL SWITCH WITH HIGH OFF ISOLATION AND BANDWIDTH

(71) Applicant: TEXAS INSTRUMENTS INCORPORATED, Dallas, TX (US)

(72) Inventors: Anukriti ANUKRITI, Kolkata (IN); Kanteti AMAR, Bangalore (IN); Anwar SADAT, Richardson, TX (US)

(21) Appl. No.: 18/443,116

(22) Filed: Feb. 15, 2024

(51) Int. Cl. H03K 17/693; H03K 17/62

(52) U.S. Cl. CPC H03K 17/693; H03K 17/6257

(57) ABSTRACT

In some examples, a circuit includes a first transistor having a control terminal and first and second terminals, the first terminal of the first transistor coupled to a first input terminal, and the second terminal of the first transistor coupled to a first output terminal. The circuit also includes a second transistor having a control terminal and first and second terminals, the first terminal of the second transistor coupled to a second input terminal, and the second terminal of the second transistor coupled to a second output terminal. The circuit also includes a third transistor having a control terminal and first and second terminals, the first terminal of the third transistor coupled to the first input terminal. The circuit also includes a first capacitor having first and second terminals, the first terminal of the first capacitor coupled to the second terminal of the third transistor, and the second terminal of the first capacitor coupled to the second output terminal. The circuit also includes a second capacitor having first and second terminals, the first terminal of the second capacitor coupled to the second input terminal. The circuit also includes a fourth transistor having a control terminal and first and second terminals, the first terminal of the fourth transistor coupled to the second terminal of the second capacitor, and the second terminal of the fourth transistor coupled to the first output terminal.

### BACKGROUND

A switching, or switch, circuit has a control terminal and has first and second terminals. Responsive to a control signal being in a first state (e.g., asserted, having a particular logic level, having a voltage of a particular value with respect to a threshold, etc.), the switching circuit provides a signal received at its first terminal to its second terminal. In this way, the switching circuit is “on.” Responsive to the control signal being in a second state (e.g., deasserted, having an opposite logic level, having a voltage of a particular value with respect to a threshold, etc.), the switching circuit theoretically does not provide the signal received at its first terminal to its second terminal. In this way, the switching circuit is theoretically “off.”

### SUMMARY

In some examples, a circuit includes a first transistor having a control terminal and first and second terminals, the first terminal of the first transistor coupled to a first input terminal, and the second terminal of the first transistor coupled to a first output terminal. The circuit also includes a second transistor having a control terminal and first and second terminals, the first terminal of the second transistor coupled to a second input terminal, and the second terminal of the second transistor coupled to a second output terminal. The circuit also includes a third transistor having a control terminal and first and second terminals, the first terminal of the third transistor coupled to the first input terminal. The circuit also includes a first capacitor having first and second terminals, the first terminal of the first capacitor coupled to the second terminal of the third transistor, and the second terminal of the first capacitor coupled to the second output terminal. The circuit also includes a second capacitor having first and second terminals, the first terminal of the second capacitor coupled to the second input terminal. The circuit also includes a fourth transistor having a control terminal and first and second terminals, the first terminal of the fourth transistor coupled to the second terminal of the second capacitor, and the second terminal of the fourth transistor coupled to the first output terminal.

In some examples, a circuit includes a first switch configured in a first operational state to receive a first signal at a first terminal of the first switch and provide the first signal at a second terminal of the first switch, and in a second operational state to block the first signal from the second terminal of the first switch. The circuit also includes a second switch configured in the first operational state to receive a second signal at a first terminal of the second switch and provide the second signal at a second terminal of the second switch, and in the second operational state to block the second signal from the second terminal of the second switch. The circuit also includes a third switch having a first terminal coupled to the first terminal of the first switch, the third switch configured in the second operational state to superimpose the first signal at the second terminal of the second switch. The circuit also includes a first capacitor coupled in series between the second terminal of the third switch and the second terminal of the second switch, the first capacitor having a capacitance equal to an input to output capacitance of the third switch. The circuit also includes a fourth switch having first and second terminals, the second terminal of the fourth switch coupled to the second terminal of the first switch, wherein the fourth switch is configured in the second operational state to superimpose the second signal at the second terminal of the first switch. The circuit also includes a second capacitor coupled in series between the first terminal of the second switch and the first terminal of the fourth switch, the second capacitor having a capacitance equal to an input to output capacitance of the fourth switch.

### BRIEF DESCRIPTION OF THE DRAWINGS

FIG. 1 is a block diagram of an example system.

FIG. 2 is a block diagram of an example of the differential switching circuit

FIG. 3 is a schematic diagram of an example of the differential switching circuit

FIG. 4 is a flowchart of an example method.

FIG. 5 is a diagram of performance of an example of the differential switching circuit

### DETAILED DESCRIPTION

As described above, a switching, or switch, circuit has a control terminal and has first and second terminals. Responsive to a control signal being in a first state (e.g., asserted, having a particular logic level, having a voltage of a particular value with respect to a threshold, etc.), the switching circuit provides a signal received at its first terminal to its second terminal. In this way, the switching circuit is “on.” Responsive to the control signal being in a second state (e.g., deasserted, having an opposite logic level, having a voltage of a particular value with respect to a threshold, etc.), the switching circuit theoretically does not provide the signal received at its first terminal to its second terminal. In this way, the switching circuit is theoretically “off.” However, in application, leakage may occur between the first and second terminals of the switching circuit even when the switching circuit is theoretically off. In this way, the switching circuit still may provide the signal, or some portion of the signal, received at its first terminal to its second terminal. For example, parasitic effects of the switching circuit between its first and second terminals, such as parasitic capacitance, may create a path for the leakage, and this effect may be increased for signals having high frequencies for which the parasitic capacitance has low equivalent series resistance. Such leakage may be undesirable in certain application environments and may render the switching circuit unsuitable for use in the those certain application environments. OFF isolation may refer to an amount of attenuation provided by the switching circuit between its first and second terminals while the switching circuit is theoretically off. Generally, the greater the value of OFF isolation, the less leakage that occurs in the switching circuit.

In some application environments, such as differential switching, OFF isolation may be increased by including cross-coupled capacitors coupled between respective input and output terminals of opposing polarities of the differential switching circuit. However, these cross-coupled capacitors may decrease, or otherwise adversely affect, bandwidth. Thus, a comparatively high OFF isolation and a large, or wide, bandwidth may be tradeoff design considerations, where a circuit can have one but not both. This may limit the application environments for some differential switching circuits.

Examples of this description provide for a differential switching circuit providing both high OFF isolation and large bandwidth. For example, at least some differential switching circuits of this description provide for an OFF isolation of about −53.49 decibels (dB) for a signal having a frequency of about 250 megahertz (MHz), and a bandwidth of about 2.625 gigahertz (GHz). In some examples, the differential switching circuit includes first and second switching circuits that operate as passing switches, providing or not providing respective components of a differential input signal as a differential output signal responsive to a control signal being in a first state. The differential switching circuit also includes third and fourth cross-coupled switching circuits. The third and fourth cross-coupled switching circuits are coupled in series with first and second capacitive components (e.g., capacitors) that each have a capacitance approximately equal to a capacitance present in the first and second switching circuits between their first and second terminals. In at least some examples, including the capacitive components having capacitances approximately equal to the capacitance present in the first and second switching circuits between their first and second terminals, switched via the third and fourth switches, respectively, mitigates the reduction in bandwidth of the differential switching circuit, described above, enabling both high OFF isolation and high bandwidth.

For example, responsive to a control signal being in a first state, a first switching circuit may provide a first signal (e.g., a positive component of a differential signal) from its first terminal to its second terminal, and a second switching circuit may provide a second signal (e.g., a negative component of the differential signal) from its first terminal to its second terminal. A third switching circuit may be coupled between the first terminal of the first switching circuit and a first terminal of a first capacitor having a second terminal coupled to the second terminal of the second switching circuit. A second capacitor may have a first terminal coupled to the first terminal of the second switching circuit and a fourth switching circuit may be coupled between a second terminal of the second capacitor and the second terminal of the first switching circuit. In this way, the third and fourth switching circuits are cross-coupled switching circuits. In an example, the third and fourth switching circuits may have characteristics substantially similar to the first and second switching circuits (e.g., same transistor size, approximately same capacitance or parasitic capacitance, approximately same equivalent series resistance, or the like. Responsive to the control signal being in the first state, the third and fourth switching circuits are non-conductive (e.g., turned off). Responsive to the control signal transitioning to be in a second state, the first and second switching circuits may become non-conductive (e.g., turned off) and the third and fourth switching circuits may become conductive (e.g., turned on). Thus, the third and fourth switching circuits, together with the first and second capacitors, superimpose the positive component of the differential signal at a terminal at which the negative component of the differential signal is normally provided, and vice versa. Such superimposition may provide for a comparatively high OFF isolation in the differential switching circuit, while the first and second capacitors being switched via the third and fourth switching circuits may mitigate adverse effects of the first and second capacitors on a bandwidth of the differential switching circuit.

For example, by including separate, physical capacitive components, those capacitive components may be switched by the third and fourth switching circuits. This may substantially isolate the capacitive components from input and/or output terminals of the differential switching circuit during a time in which the first and second switching circuits are conductive, and may thereby mitigate an effect of the capacitive components on a bandwidth of the differential switching circuit. The first and second switching circuits may be sized according to a first width to length ratio and the third and fourth switching circuits may be sized according to a second width to length ratio that is smaller than the first width to length ratio. In this way, the third and fourth switching circuits may have an equivalent series resistance substantially larger than that of the first and second switching circuits and a parasitic capacitance between their respective first and second terminals substantially less than that of the first and second switching circuits. The substantially higher equivalent series resistance may prevent leakage through the third and fourth switching circuits, as described above, such that by including the capacitive components separate from the third and fourth switching circuits and decreasing the size of the third and fourth switching circuits, both high OFF isolation via the series-coupled capacitive circuits and high bandwidth via the cross-coupled third and fourth switching circuits are achieved.

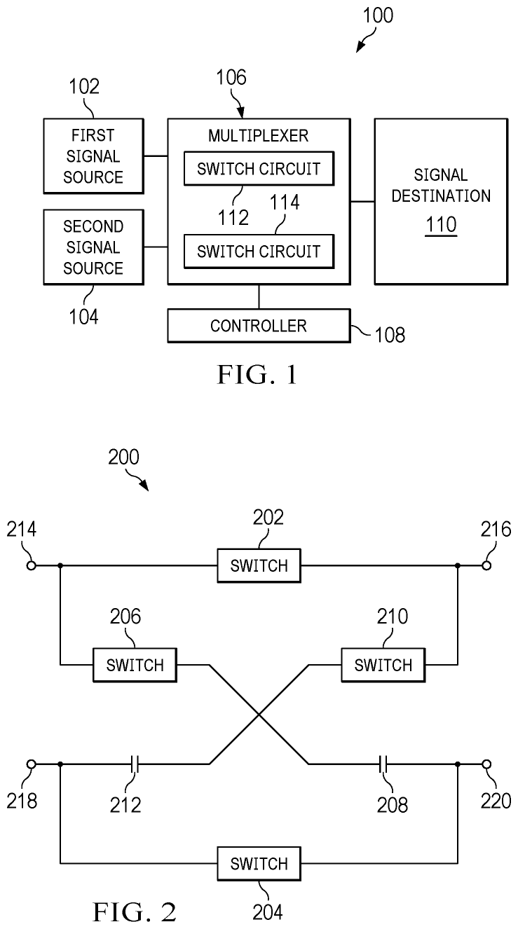

FIG. 1 is a block diagram of an example system 100. In some examples, the system 100 is representative of any electronic device in which multiple signals are provided by respective input sources and one of those signals is selected and provided to a destination. For example, the system 100 may be representative of, or included in, an automobile or other transportation device, a computing device (e.g., server computer, desktop computer, tablet computer, etc.), a smartphone, a wearable device, an audio device, or the like. In an example, the system 100 includes a first signal source 102, a second signal source 104, a multiplexer 106, a controller 108, and a signal destination 110. The multiplexer 106 includes a switching circuit 112 and a switching circuit 114. In some examples, the switching circuit 112 and the switching circuit 114 are each differential switching circuits.

In an example, the first signal source 102 is any device capable of providing a first signal, either by generating the first signal or based on manipulation of a signal received from another component or device to form the first signal. Similarly, the second signal source 104 is any device capable of providing a second signal, either by generating the second signal or based on manipulation of a signal received from another component or device to form the second signal. The multiplexer 106 has a first input coupled to an output of the first signal source 102, a second input coupled to an output of the second signal source 104, a control or select input coupled to an output of the controller 108, and an output. The signal destination 110 is any device capable of receiving a signal, the scope of which is not limited herein.

In an example, the signal destination 110 has an input coupled to the output of the multiplexer 106. In an example, the switching circuit 112 is configured to receive the first signal from the first signal source 102 and the switching circuit 114 is configured to receive the second signal from the second signal source 104. Based on control by the controller 108, one of the switching circuit 112 or the switching circuit 114 provides its respective input signal to the signal destination 110 while the other of the switching circuit 112 or the switching circuit 114 blocks its respective input signal from reaching the signal destination 110. The controller 108 may be any suitable component or device capable of providing a control signal or control signals to the multiplexer 106 for controlling operation of the switching circuits 112, 114. For example, the controller 108 may be a microcontroller, a processor, a microprocessor, a logic circuit, an analog circuit, or any other circuit or component capable of determining a value of one or more control signals and providing the one or more control signals to the multiplexer 106. While shown as single, or single-ended, couplings between various components of the system 100, any one or more of the couplings shown may be representative of multiple couplings, such as differential couplings.

In some examples, the switching circuit 112 and the switching circuit 114 are each differential switching circuits such that the first signal and the second signal are differential signals, each having respective positive and negative components. The switching circuit 112 and the switching circuit 114 may operate in a substantially similar manner. As such, description with respect to the switching circuit 112 is also applicable to the switching circuit 114, but will not be repeated herein. Additionally, while shown as components of a multiplexer, in various examples the switching circuits 112, 114 may instead be implemented in a demultiplexer and/or in any other device in which switching may be useful.

In an example, the switching circuit 112 receives the first signal from the first signal source 102, where the first signal is a differential signal including positive and negative components. Responsive to a control signal received from the controller 108 being in a first state (e.g., being asserted, having a value greater than a threshold, having a logic high (e.g., logic “1”) value, or the like), the switching circuit 112 provides the first signal to the signal destination 110 via a signal pass path. While described herein as the switching circuit 112 providing the first signal to the signal destination 110, it should be understood that the signal provided to the signal destination 110 may not be the literal first signal received by the switching circuit 112 from the first signal source 102. Rather, the signal provided to the signal destination 110 may be based on, or otherwise representative of, the first signal received by the switching circuit 112 from the first signal source 102. For example, switching losses, parasitic circuit effects, or other factors may alter a value of the signal provided to the signal destination 110 in comparison to the first signal.

Responsive to a control signal received from the controller 108 being in a second state (e.g., being deasserted, having a value less than a threshold, having a logic low (e.g., logic “0”) value, or the like), the switching circuit 112 blocks the first signal from the signal destination 110. For example, the switching circuit 112 disables the signal pass path between the first signal source 102 and the signal destination 110 through the switching circuit 112. In some examples, despite the signal pass path being disabled, leakage may occur through the signal pass path, as described above. To reduce the effects of this leakage, the switching circuit 112 includes a superimposition path. The superimposition path is cross-coupled between differential inputs and outputs of the switching circuits 112. For example, a positive differential input of the switching circuit 112 is coupled to a negative differential output of the switching circuit 112 via a first superimposition path, and a negative differential input of the switching circuit 112 is coupled to a positive differential output of the switching circuit 112 via a second superimposition path. In some examples, by superimposing the differential components of the first signal at the outputs of the switching circuit 112 having opposite polarities of the signal components provided at those outputs, the signal components sum to a value of zero, canceling each other out. In this way, the effects of the leakage are reduced, disabling the signal pass path through the switching circuit 112. In some examples, a capacitive component is coupled in the superimposition path (e.g., a first capacitive component in the first superimposition path and a second capacitive component in the second superimposition path) having a capacitance approximately equal to a parasitic capacitance present in the signal pass path. In some examples, the capacitance is switched such that a bandwidth of the switching circuit 112 is increased in comparison to an example of the switching circuit 112 including the capacitive component but without the capacitive component being switched.

FIG. 2 is a block diagram of an example of a differential switching circuit 200. In some examples, the differential switching circuit 200 is suitable for implementation as the switching circuit 112 and/or the switching circuit 114 of the system 100 of FIG. 1. In other examples, the differential switching circuit 200 is suitable for implementation in any application environment in which signal switching may be useful, such as Universal Serial Bus (USB) capable devices, High-Definition Multimedia Interface (HDMI) capable devices, Peripheral Component Interconnect (PCI) capable devices, or the like. For example, the differential switching circuit 200 may be particularly suitable for implementation in application environments in which it may be useful to have both a high OFF isolation (e.g., greater than or equal to −40 dB) for high frequency (e.g., greater than or equal to 250 MHz) signals, as well as a large bandwidth (e.g., greater than or equal to about 2.6 GHz).

In an example, the differential switching circuit 200 includes a switch 202, a switch 204, a switch 206, a capacitor 208, a switch 210, and a capacitor 212. In an example, the switch 202 has a first terminal coupled to an input terminal 214 and a second terminal coupled to an output terminal 216. The switch 204 has a first terminal coupled to an input terminal 218 and a second terminal coupled to an output terminal 220. The switch 206 has a first terminal coupled to the input terminal 214, and has a second terminal. The capacitor 208 has a first terminal coupled to the second terminal of the switch 206, and has a second terminal coupled to the output terminal 216. The switch 210 has a first terminal coupled to the input terminal 218, and has a second terminal. The capacitor 212 has a first terminal coupled to the second terminal 210, and has a second terminal coupled to the output terminal 216. In an example, each of the switches 202, 204, 206, and 210 also have control terminals (not shown) at which respective control signals are received. In some examples, the switches 202, 204 receive the same control signal, or control signals having a same first value, and the switches 206, 210 receive a different control signal, or controls signals having a same second value, where the first and second values are opposites. In this way, the switches 202, 204 may be conductive, or turned on, while the switches 206, 210 are non-conductive, or turned off, and vice versa. In an example, the differential switching circuit 200 receives a differential input signal at the input terminal 214 and the input terminal 218. For example, a positive component of the differential input signal is received at the input terminal 214 and a negative component of the differential input signal is received at the input terminal 218. Similarly, the output terminal 216 may be an output terminal for a positive component of a differential output of the differential switching circuit 200 and the output terminal 220 may be an output terminal for a negative component of a differential output of the differential switching circuit 200.

While certain terminals are described herein as input or output, in various examples their implementation may be reversed. For example, the differential switching circuit 200 may be bidirectional such that described inputs are in fact outputs, and described outputs are in fact inputs.

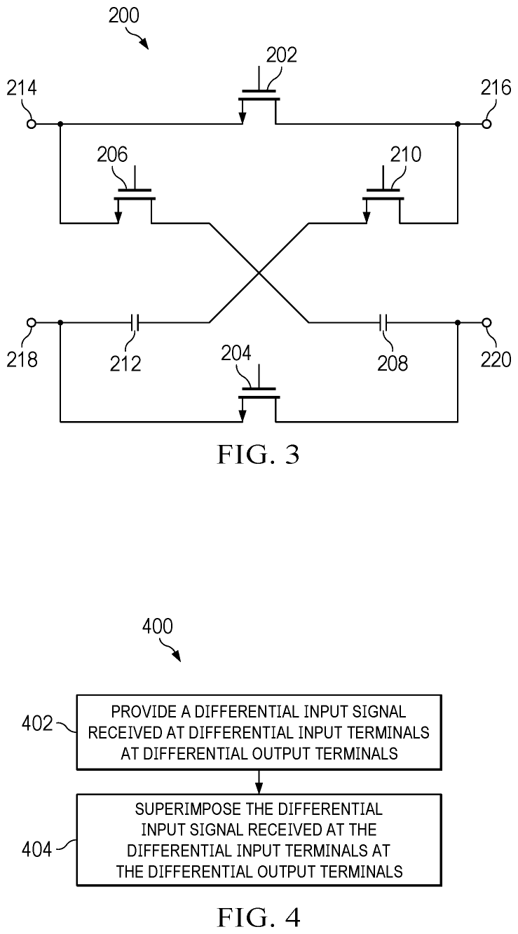

In an example, switches 202, 204, 206, 210 are each implemented as electro-mechanical devices, such as relays or other forms of electro-mechanical components. In another examples, switches 202, 204, 206, 210 are each implemented as solid-state devices, such as transistors. For example, the switches 202, 204, 206, 210 may be implemented as bi-polar junction transistor (BJT) devices, field effect transistor (FET) devices (such as metal oxide semiconductor FETS (MOSFETS), diodes, or according to any other suitable solid-state technology. An example of the differential switching circuit 200 in which the switches 202, 204, 206, 210 are each implemented as n-channel FETs is shown in FIG. 3.

In an example, the switch 202 has a parasitic, or inherently occurring, capacitance between its first and second terminals. Similarly, the switch 204 has a parasitic, or inherently occurring, capacitance between its first and second terminals. In some examples, particularly in the presence of high frequency signals, these parasitic capacitances may result in leakage, as described above. In an example, the capacitor 208 has a capacitance approximately equal in value to the parasitic capacitance between the first and second terminals of the switch 202. Similarly, the capacitor 212 has a capacitance approximately equal in value to the parasitic capacitance between the first and second terminals of the switch 204.

Responsive to the control signal received by the differential switching circuit 200, such as from the controller 208, being in a first state, the switch 202 is conductive and provides the positive component of the differential input signal to the output terminal 216. Similarly, responsive to the control signal received by the differential switching circuit 200 being in the first state, the switch 204 is conductive and provides the negative component of the differential input signal to the output terminal 220. Also responsive to the control signal received by the differential switching circuit 200 being in the first state, the switches 206, 210 are non-conductive, functioning as an open circuit.

Responsive to the control signal received by the differential switching circuit 200, such as from the controller 208, being in a second state, the switch 202 is non-conductive and, theoretically, blocks the positive component of the differential input signal to the output terminal 216. Similarly, responsive to the control signal received by the differential switching circuit 200 being in the second state, the switch 204 is non-conductive and, theoretically, blocks the negative component of the differential input signal to the output terminal 220. However, as described above, at least some leakage of the positive component of the differential input signal may occur through the switch 202 between the input terminal 214 and the output terminal 216. Similarly, at least some leakage of the negative component of the differential input signal may occur through the switch 204 between the input terminal 218 and the output terminal 220.

To mitigate the effects of this leakage, responsive to the control signal received by the differential switching circuit 200 being in the second state, the switches 206, 210 are conductive. In this way, responsive to the control signal received by the differential switching circuit 200 being in the second state, the positive component of the differential input signal is superimposed by the switch 206 and capacitor 208 at the output terminal 220 (e.g., the output terminal for a negative component of the differential output of the differential switching circuit 200). Similarly, the negative component of the differential input signal is superimposed by the switch 210 and capacitor 212 at the output terminal 216 (e.g., the output terminal for a positive component of the differential output of the differential switching circuit 200).

In some examples, by switching the capacitors 208, 212 via the switches 206, 210, the capacitors 208, 212 are isolated from the differential input signal while the switches 202, 204 are conductive. This may increase the bandwidth of the differential switching circuit 200 in comparison to an example that excludes the switches 206, 210 but includes the capacitors 208, 212. For example, as described above, in examples which may omit the capacitors 208, 212, the switches 206, 210 may have a larger size, substantially similar to that of the switches 202, 204, such as to provide approximately equal parasitic capacitances between respective first and second terminals of the switches. However, this may lead to leakage through the switches 206, 210, as described above with respect to the switches 202, 204 via their respective parasitic capacitances, thereby reducing bandwidth of the differential switching circuit 200. Similarly, by including the capacitors 208, 212, but omitting the switches 206, 210, superimposition paths may be formed for cancelling the leakage through the switches 202, 204, as described above herein, but at an operational cost of reducing a bandwidth of the differential switching circuit 200. By including the capacitors 208, 212 as separate components, switched by the switches 206, 210, and each having capacitances approximately equal to the parasitic capacitances provided by the switches 202, 204 between their first and second terminals, the switches 206, 210 may be sized substantially smaller than the switches 202, 204. In this way, the switches 206, 210 may have a large equivalent series resistance which inhibits the leakage described above. By inhibiting the leakage, bandwidth of the differential switching circuit 200 is increased while still enabling differential signal canceling through superimposition, as described above, to achieve a high OFF isolation.

FIG. 4 is a flowchart of an example method 400. In an example, the method 400 may be implemented by a system such as the system 100. For example, the method 400 may be implemented by the multiplexer 106 (such as via the switching circuit 112), the controller 108, or by a combination of the multiplexer 106 and the controller 108. In an example, the method 400 is implemented to perform switching of a signal, such as a differential signal, between a signal source and a signal destination.

At operation 402, a differential input signal received at differential input terminals is provided at differential output terminals. In some examples, the differential input signal received at the differential input terminals is provided at the differential output terminals responsive to receipt of a control signal in a first state, as described above. The control signal may be received from a controller, such as the controller 108. In some examples, the differential input signal is provided from the differential input terminals to the differential output signals via signal pass paths.

At operation 404, the differential input signal received at the differential input terminals is superimposed at the differential output terminals. In some examples, the differential input signal received at the differential input terminals is superimposed at the differential output terminals responsive to receipt of the control signal in a second state, as described above. In this way, responsive to the control signal being in the second state, a positive component of the differential input signal is superimposed at a differential output terminal for a negative component of a differential output signal. Similarly, a negative component of the differential input signal is superimposed at a differential output terminal for a positive component of a differential output signal. In some examples, the superimposition is performed via superimposition signal paths each having a series capacitance approximately equal to a parasitic capacitance of the signal pass paths. The series capacitance may be switched or gated. For example, during a first time in which switches (e.g., the switches 202, 204) are conductive in a forward direction, electrically coupling the differential input terminals to differential output terminals of the same polarity via the signal pass paths, second switches (e.g., the switches 206, 210) may substantially electrically isolate the series capacitance from the differential input terminals. This electrical isolation may increase an operational bandwidth of the multiplexer in comparison to omitting the second switches, such as described with respect to the various examples described above herein. Conversely, during a second time in which switches (e.g., the switches 202, 204) are non-conductive in a forward direction, substantially electrically isolating the differential input terminals from the differential output terminals of the same polarity via the signal pass paths, the second switches (e.g., the switches 206, 210) may be conductive in the forward direction to provide the differential input signal, via the series capacitors, according to the superimposition signal paths.

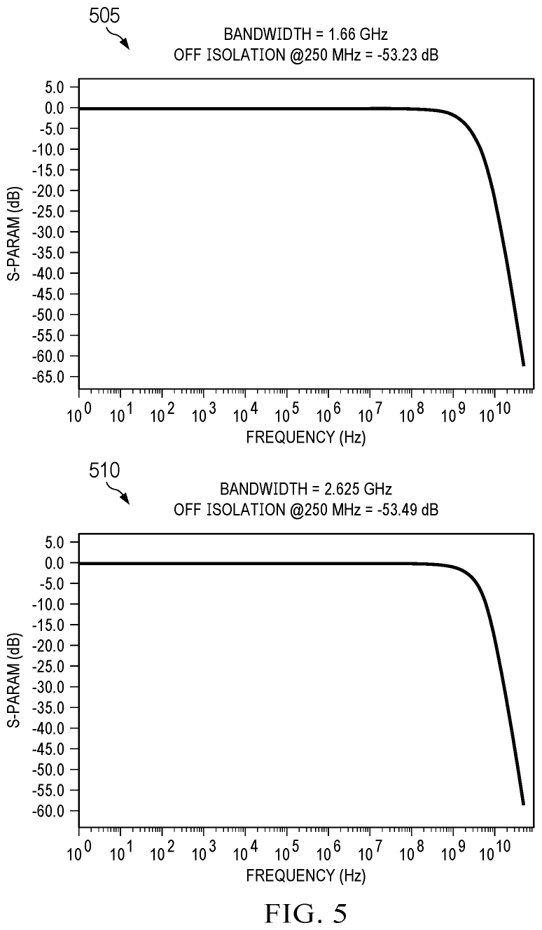

FIG. 5 is a diagram of performance of an example of the differential switching circuit 200. For example, the diagram 505 is representative of performance of a differential switching circuit, such as the differential switching circuit 200, which includes the capacitors 208, 212 but omits the switches 206, 210. In contrast, the diagram 510 is representative of performance of the differential switching circuit 200, including the capacitors 208, 212 switched by the switches 206, 210. As shown by the diagram 505, for an OFF isolation of approximately −53.23 dB for a signal having a frequency of about 250 MHz, a differential switching circuit such as the differential switching circuit 200 including the capacitors 208, 212 but omitting the switches 206, 210 has a bandwidth of approximately 1.66 GHz. However, as shown by the diagram 510, by including the capacitors 208, 212 switched by the switches 206, 210, the bandwidth of the differential switching circuit is increased. For example, as shown by the diagram 510, for an OFF isolation of approximately −53.49 dB for a signal having a frequency of about 250 MHz, the differential switching circuit 200 including the capacitors 208, 212 switched by the switches 206, 210, has a bandwidth of approximately 2.625 GHz.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. Furthermore, a voltage rail or more simply a “rail,” may also be referred to as a voltage terminal and may generally mean a common node or set of coupled nodes in a circuit at the same potential.

What is claimed is:

1. A circuit, comprising:
a first transistor having a control terminal and first and second terminals, the first terminal of the first transistor coupled to a first input terminal, and the second terminal of the first transistor coupled to a first output terminal;
a second transistor having a control terminal and first and second terminals, the first terminal of the second transistor coupled to a second input terminal, and the second terminal of the second transistor coupled to a second output terminal;
a third transistor having a control terminal and first and second terminals, the first terminal of the third transistor coupled to the first input terminal;
a first capacitor having first and second terminals, the first terminal of the first capacitor coupled to the second terminal of the third transistor, and the second terminal of the first capacitor coupled to the second output terminal;
a second capacitor having first and second terminals, the first terminal of the second capacitor coupled to the second input terminal; and
a fourth transistor having a control terminal and first and second terminals, the first terminal of the fourth transistor coupled to the second terminal of the second capacitor, and the second terminal of the fourth transistor coupled to the first output terminal.

2. The circuit of claim 1, wherein the control terminals of the first and second transistors are coupled together.

3. The circuit of claim 1, wherein the control terminals of the third and fourth transistors are coupled together.

4. The circuit of claim 1, wherein the first and second input terminals form a differential input and the first and second output terminals form a differential output.

5. The circuit of claim 1, wherein a capacitance of the first capacitor is equal to a first terminal to second terminal capacitance of the third transistor, and wherein a capacitance of the second capacitor is equal to a first terminal to second terminal capacitance of the fourth transistor.

6. The circuit of claim 1, wherein the first and second transistors each have a first width to length ratio, and wherein the third and fourth transistors each have a second width to length ratio.

7. The circuit of claim 6, wherein the second width to length ratio is less than the first width to length ratio.

8. The circuit of claim 1, wherein the first and second transistors are controllable to be conductive in a forward direction in a first operational state and non-conductive in the forward direction in a second operational state, and wherein the third and fourth transistors are controllable to be non-conductive in the forward direction in the first operational state and conductive in the forward direction in the second operational state.

9. The circuit of claim 1, wherein each of the first, second, third, and fourth transistors are field effect transistors.

10. The circuit of claim 1, wherein each of the first, second, third, and fourth transistors are bipolar junction transistors.

11. A circuit, comprising:
a first switch configured in a first operational state to receive a first signal at a first terminal of the first switch and provide the first signal at a second terminal of the first switch, and in a second operational state to block the first signal from the second terminal of the first switch;
a second switch configured in the first operational state to receive a second signal at a first terminal of the second switch and provide the second signal at a second terminal of the second switch, and in the second operational state to block the second signal from the second terminal of the second switch;
a third switch having a first terminal coupled to the first terminal of the first switch, the third switch configured in the second operational state to superimpose the first signal at the second terminal of the second switch;
a first capacitor coupled in series between the second terminal of the third switch and the second terminal of the second switch, the first capacitor having a capacitance equal to an input to output capacitance of the third switch;
a fourth switch having first and second terminals, the second terminal of the fourth switch coupled to the second terminal of the first switch, wherein the fourth switch is configured in the second operational state to superimpose the second signal at the second terminal of the first switch; and
a second capacitor coupled in series between the first terminal of the second switch and the first terminal of the fourth switch, the second capacitor having a capacitance equal to an input to output capacitance of the fourth switch.

12. The circuit of claim 11, further comprising a controller coupled to the first switch, the second switch, the third switch, and the fourth switch, wherein the controller is configured to:
provide a first control signal to the first switch and the second switch to control the first switch and the second switch to operation in the first operational state or the second operational state; and
provide a second control signal to the third switch and the fourth switch to control the third switch and the fourth switch to operation in the first operational state or the second operational state.

13. The circuit of claim 12, wherein the controller is configured to provide the first control signal and the second control signal having opposite binary values.

14. The circuit of claim 12, wherein:
the first switch has a control terminal, the first switch is configured to receive the first input signal at the first terminal of the first switch, the second terminal of the first switch is coupled to a first output terminal of the circuit, and the control terminal of the first switch is coupled to the controller, and
the second switch has a control terminal, the second switch is configured to receive the second input signal at the first terminal of the second switch, the second terminal of the second switch is coupled to a second output terminal of the circuit, and the control terminal of second switch is coupled to the controller.

15. The circuit of claim 14, wherein:
the third switch has a control terminal coupled to the controller, and
the fourth switch has a control terminal coupled to the controller.

16. The circuit of claim 11, wherein each of the first, second, third, and fourth switches are transistors.

17. The circuit of claim 16, wherein each of the first, second, third, and fourth switches are field effect transistors.

18. The circuit of claim 16, wherein each of the first, second, third, and fourth switches are bipolar junction transistors.

19. The circuit of claim 16, wherein the first and second transistors have a first width to length ratio, and wherein the third and fourth transistors have a second width to length ratio that is less than the first width to length ratio.

20. The circuit of claim 11, wherein the first signal and the second signal are each respective components of a differential signal.
